(19) United States
(12) Patent Application Publication
(10) Pub. No.: US 2023/0145250 A1
(43) Pub. Date: May 11, 2023

(54) SUBSTRATE STRUCTURE, ON-CHIP STRUCTURE, AND METHOD FOR MANUFACTURING ON-CHIP STRUCTURE

(71) Applicant: CHONGQING KONKA PHOTOELECTRIC TECHNOLOGY RESEARCH INSTITUTE CO., LTD., Chongqing (CN)

(72) Inventors: Chunlin FAN, Chongqing (CN); Bin WANG, Chongqing (CN); Qing WANG, Chongqing (CN)

(21) Appl. No.: 17/433,614

(22) PCT Filed: Jul. 30, 2020
(86) PCT No.: PCT/CN2020/105915

§ 371 Date: Aug. 25, 2021

(51) Int. Cl. H01L 33/20; H01L 33/38; H01L 33/32; H01L 33/00; H01L 33/62

(52) U.S. Cl. CPC H01L 33/20; H01L 33/382; H01L 33/32; H01L 33/007; H01L 33/62; H01L 2933/0016; H01L 2933/0066

(57) ABSTRACT

The application relates to a substrate structure, an on-chip structure, and a method for manufacturing the on-chip structure. The substrate structure includes a substrate body and an electrothermal layer. The electrothermal layer is arranged on a surface of the substrate body for growing an epitaxial layer. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with the substrate structure can be thermally decomposed and separated from the substrate structure.

### TECHNICAL FIELD

The application relates to the field of mass transfer technologies in a Micro LED (Micro Light Emitting Diode), and in particular, to a substrate structure, an on-chip structure, and a method for manufacturing an on-chip structure.

### BACKGROUND

As a new generation of display technology, an Micro LED has performances of higher brightness, better luminous efficiency, low power consumption and long life compared to LCD (Liquid Crystal Display) and OLED (Organic Light Emitting Diode) technologies. In a manufacturing process of a miniature light-emitting diode, mass transfer serves as a key point for technological breakthrough. The process of the miniature light-emitting diode mainly includes a laser lift off (LLO), the mass transfer as well as inspection and repair processes. Laser lift off technology is an important part of mass-transfer technology. The laser lift off technology mainly utilizes a band gap difference between an epitaxial layer and a substrate, and utilizes a laser radiation to thermally decompose the epitaxial layer, thereby separating the epitaxial layer from the substrate.

However, when utilizing the laser lift off technology to separate the epitaxial layer from the substrate, on the one hand, fluctuations of laser energy easily cause a problem of poor lift off, and on the other hand, different materials of the epitaxial layer and the substrate have different laser absorption bands in the laser lift off, and a laser lift off apparatus are expensive, which also greatly increases manufacturing costs.

### SUMMARY

In view of the forgoing shortcomings of a prior art, an objective of this application is to provide a substrate structure, an on-chip structure, and a method for manufacturing the on-chip structure, aiming to solve problems of poor lift off of an epitaxial layer caused by a laser lift off method in the prior art, and high costs of a laser lift off apparatus.

There is provided a substrate structure, including: a substrate body; and an electrothermal layer arranged on a surface of the substrate body for growing an epitaxial layer.

In the forgoing substrate structure, the electrothermal layer is provided on the surface of the substrate body for growing the epitaxial layer, which is equivalent to adding the electrothermal layer between the substrate body and the epitaxial layer of a chip. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with the substrate structure can be thermally decomposed and separated from the substrate structure. Since a heating process of the electrothermal layer can be flexibly controlled, a temperature can be controlled, and the heating can be repeated, a lift off effect of the epitaxial layer is improved, an active layer above is not damaged, and a lift off yield is improved. In addition, there is no need to utilize a laser lift off apparatus, which greatly reduces costs of the lift off process. In a word, the forgoing substrate structure provided by the application effectively solves the problems that the laser lift off method in the prior art is likely to result in poor lift off of the epitaxial layer and high costs of the apparatus.

In addition, the forgoing substrate structure provided by the application also has the advantages of simple structure and high reliability. During an electrothermal lift off process, the substrate body is not damaged as easily as a laser lift off, and a recycling performance of a substrate is better.

Based on the same inventive concept, this application also provides an on-chip structure, including a substrate and an epitaxial layer growing on the substrate, wherein the substrate is the forgoing substrate structure provided by the application. In the on-chip structure, an electrothermal layer is added between a substrate body and the epitaxial layer. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with the substrate structure can be thermally decomposed and separated from the substrate structure. Since a heating process of the electrothermal layer can be flexibly controlled, a temperature can be controlled, and the heating can be repeated, a lift off effect of the epitaxial layer is improved, an active layer above is not damaged, and a lift off yield is improved. In addition, there is no need to utilize an laser lift off apparatus, which greatly reduces costs of the lift off process.

Based on the same inventive concept, this application also provides a method for manufacturing an on-chip structure, which is used for manufacturing the forgoing on-chip structure.

The method includes:

providing a substrate body;

putting the substrate body into a metal sputtering machine;

forming a layer of electrothermal layer on the substrate body by sputtering on the substrate body in the metal sputtering machine using a mask; and

depositing and growing an epitaxial layer on the electrothermal layer.

With the method, the layer of electrothermal layer can be added between the substrate body and the epitaxial layer. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with a substrate structure can be thermally decomposed and separated from the substrate structure. In addition, the method uses a metal sputtering method to manufacture the electrothermal layer, and has the advantages of high reliability, easy control of a structure and a shape of the electrothermal layer, and the like.

### BRIEF DESCRIPTION OF THE DRAWINGS

FIG. 1 is a schematic structural diagram of a substrate structure according to an embodiment of the application;

FIG. 2 is a schematic structural diagram of a substrate structure according to an embodiment of the application;

FIG. 3 is a side view of a substrate structure at an A position in FIG. 2;

FIG. 4 is a top diagram of a substrate structure according to another embodiment of the application;

FIG. 5 is a schematic structural diagram of a substrate structure according to another embodiment of the application;

FIG. 6 is a schematic structural diagram of a substrate structure according to another embodiment of the application;

FIG. 7 is a schematic structural diagram of a substrate structure according to another embodiment of the application;

FIG. 8 is a flowchart of a method for manufacturing an on-chip structure according to an embodiment of the application.

### THE DESCRIPTION OF REFERENCE SIGNS

10—substrate body; 20—electrothermal layer; 30—electrode.

### DETAILED DESCRIPTION OF THE EMBODIMENTS

To facilitate the understanding of the present disclosure, the following makes a more comprehensive description of the present disclosure with reference to the relevant drawings. Preferred embodiments of this application are shown in the drawings. However, the application can be implemented in many different forms and is not limited to the implementation described herein. On the contrary, an objective of providing these embodiments is to make the understanding of the disclosure of the present application more thorough and comprehensive.

Unless otherwise specified, all technical and scientific terms used herein have the same meaning as commonly understood by the person skilled in the art to which this application belongs. The terms used in the description of this application herein are only used for an objective of describing a specific implementation, and are not intended to limit this application.

As described in the background, a laser lift off method in a prior art easily results in poor lift off of an epitaxial layer, and relatively high costs of a laser lift off apparatus.

To solve the forgoing problems, the application provides a substrate structure, which is specifically as follows:

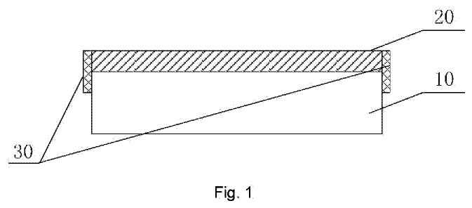

In some embodiments, there is provided a substrate structure. As shown in FIG. 1, the substrate structure includes a substrate body 10 and an electrothermal layer 20. The electrothermal layer 20 is provided on a surface of the substrate body 10 for growing an epitaxial layer.

A method of manufacturing the forgoing substrate structure is simple. For example, a mask of which a shape corresponds to that of the electrothermal layer 20 to be manufactured is positioned in a metal sputtering machine, and then the substrate body is also positioned in the metal sputtering machine. Finally, a metal sputtering process is utilized to manufacture the electrothermal layer 20 on the surface of the substrate body 10. To avoid introduction of impurities, the substrate body can be cleaned, dried, and electrostatically removed in order before metal sputtering.

To better conduct electrical conduction between the electrothermal layer 20 in the substrate structure and an external power supply, it is understandable that the forgoing substrate structure further includes an electrode 30 connected to the electrothermal layer 20 for electrically conducting the electrothermal layer 20 with the external power supply. A location and a method of the electrode 30 are not limited as long as the electrode can be connected to the external power supply. Exemplarily, the forgoing electrode 30 is connected to the electrothermal layer 20 and extends beyond the substrate body 10 to facilitate connection with the external power supply. In addition, to facilitate manufacturing and improve connection reliability, as shown in FIG. 1, the electrode 30 is connected to the electrothermal layer 20 and arranged on a sidewall of the substrate body 10.

In a specific manufacturing process, after the electrothermal layer 20 is manufactured by a metal sputtering process using a mask, the electrode 30 is formed at a positon of the sidewall of the substrate body 10 close to an end of the electrothermal layer 20 by sputtering by another mask.

Understandably, the shape or a structure of the electrothermal layer 20 can promote the epitaxial layer to be in contact with the substrate body and promote good growth of the substrate body. In addition, the epitaxial layers are evenly and fully distributed on the substrate body as far as possible, so that the epitaxial layer can be more fully and evenly heated when lifting off the epitaxial layer. For example, the structure of the electrothermal layer 20 includes a hollow grid structure and/or a curved structure.

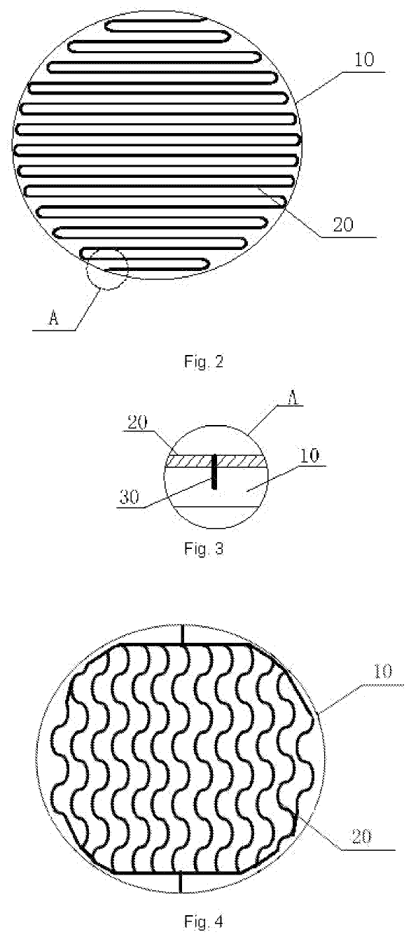

In some embodiments, the curved structure comprises a plurality of curved sections connected in series or in parallel. The curved section comprises one or more of a S-shaped curved section, a U-shaped curved section, a circular arc-shaped curved section, and a polyline section. Designing the electrothermal layer as the plurality of curved sections connected in series or in parallel is beneficial to improving structural stability of the electrothermal layer, thereby improving reliability of the on-chip structure when the epitaxial layer is lifted off. For example, as shown in FIG. 2, the curved structure includes a plurality of U-shaped line sections connected in series. As shown in FIG. 4, the curved structure includes the plurality of S-shaped curved sections connected in parallel. As shown in FIG. 5, the curved structure includes the plurality of U-shaped polyline sections connected in series. The specific electrode 30 can be provided on the sidewall of the substrate body 10 and connected to the electrothermal layer 20 as shown in FIG. 3.

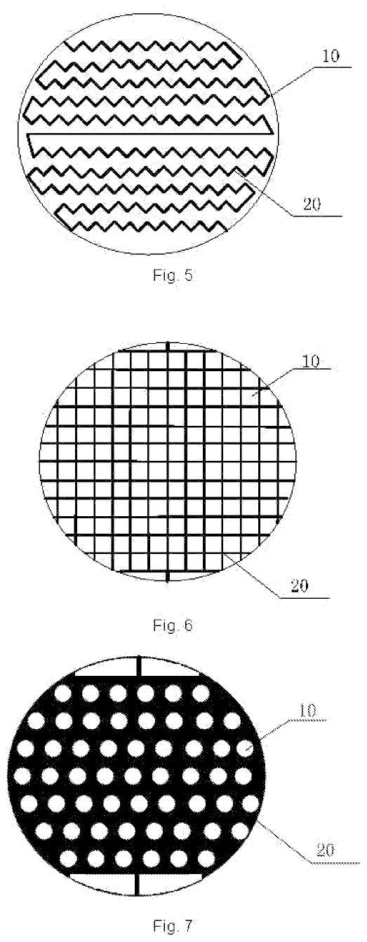

In some embodiments, the hollow grid structure includes a plurality of hollow patterns distributed in an array, and the hollow pattern includes one or more of a square, a rectangle, a circle, a trapezoid, a rhombus, and a parallelogram. The hollow grid structure is designed as the plurality of hollow patterns distributed in the array, which also helps the electrothermal layer be more fully and evenly distributed on the substrate body. During a lift off of the epitaxial layer, a temperature distribution of the electrothermal layer is more even, which is beneficial to improving efficiency and integrity of the lift off of the epitaxial layer. As shown in FIG. 6, the hollow pattern is the square. As shown in FIG. 7, the hollow pattern is the circle.

Exemplarily, the hollow grid structure has a grid line width of less than or equal to 5 nm, such as 5 nm, 4 nm, or 3 nm, and a grid line thickness of less than or equal to 10 nm, such as 10 nm, 9 nm, 8 nm, 7 nm, 6 nm, 5 nm, and the like. The hollow pattern has the longest dimension of less than or equal to 10 μm, such as 10 μm or 9 μm or 8 μm or 7 μm or 6 μm or 5 μm.

Exemplarily, the curved structure has a line width of less than or equal to 5 nm, such as 5 nm, 4 nm, or 3 nm, and a thickness of less than or equal to 10 nm, such as 10 nm, 9 nm, 8 nm, 7 nm, 6 nm, 5 nm, and the like.

In some embodiments, as shown in FIG. 2, when the electrothermal layer 20 includes U-shaped electrothermal wire sections connected in series, a distance between two branch lines in each U-shaped curved section is equal. Setting the distance between the two branch lines in each U-shaped curved section to be the same distance is beneficial to further improving a distribution evenness of the electrothermal layer on the substrate body, thereby further improving the evenness of heating when the epitaxial layer is lifted off. In addition, to make an arrangement of the electrothermal layer 20 more even, the distance of the adjacent branch lines in the two adjacent U-shaped curved sections is also equal. As long as the electrothermal layer 20 can be fully spread on a surface of the substrate body 10 and can achieve electrical conduction and the heating under actions of the electrode and the external power supply, which should be understood by the person skilled in the art, and is not repeated here.

Exemplarily, the electrothermal layer 20 is made of materials including at least one of nickel-chromium alloy, iron-chromium-aluminum alloy, tungsten, tungsten alloy, molybdenum, molybdenum alloy, and carbon fiber. The forgoing alloy materials have a high temperature resistance and a stable structure, can still maintain an original shape of a heating wire in a high temperature environment and have a longer life.

The substrate body 10 can be made of a material commonly used in the art, such as a sapphire substrate, a silicon substrate, a silicon carbide substrate, or a silicon dioxide substrate.

In an actual implementation process, after the electrothermal layer 20 is manufactured, a line width inspection is performed, and an AOI (Automatic Optic Inspection) apparatus can be utilized for defect detection. The line width inspection is to detect a width, a spacing, a height, etc. of a line. The AOI apparatus mainly detects a production morphology of the electrothermal layer, such as: whether there is a broken wire of an electrothermal wire, and whether there is a particle (dust) influence (a large particle coverage causes a disconnection of a circuit). A qualified product can be configured as a final substrate structure for a subsequent manufacturing process of the epitaxial layer, such as MOCVD (Metal-organic Chemical Vapor Deposition) apparatus for a subsequent process.

In some embodiments, there is provided an on-chip structure, including the forgoing substrate structure. The on-chip structure is also called an Chip On Wafer (COW). In the on-chip structure, an electrothermal layer is added between a substrate body and an epitaxial layer. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with the substrate structure can be thermally decomposed and separated from the substrate structure. Since a heating process of the electrothermal layer can be flexibly controlled, a temperature can be controlled, and the heating can be repeated, a lift off effect of the epitaxial layer is improved, an active layer above is not damaged, a lift off yield is improved. In addition, there is no need to utilize a laser lift off apparatus, which greatly reduces costs of the lift off process.

In addition, the substrate structure also has the advantages of simple structure and high reliability. During an electrothermal lift off process, the substrate body is not damaged as easily as a laser lift off, and a recycling performance of a substrate is better.

Exemplarily, the forgoing on-chip structure includes the substrate structure and the epitaxial layer in order from bottom to top, and the epitaxial layer can include one or more of a gallium nitride layer, a gallium arsenide layer, an aluminum arsenide layer, and an aluminum nitride layer. The plurality of forgoing epitaxial layers can all be thermally decomposed during a heating process of the electrothermal layer, so as to achieve an objective of lift off of a surface of the substrate. For example, the epitaxial layer is the gallium nitride layer, and the substrate body is a sapphire substrate.

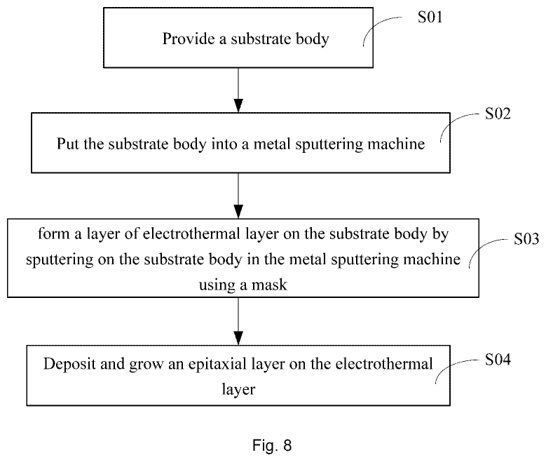

In an actual manufacturing process, as shown in FIG. 8, there is provided a method for manufacturing the forgoing on-chip structure, including the following operations:

S01: providing the forgoing substrate body;

S02: putting the substrate body into a metal sputtering machine;

S03: forming a layer of electrothermal layer on the substrate body by sputtering on the substrate body in the metal sputtering machine using a mask; and

S04: depositing and growing the epitaxial layer on the electrothermal layer.

With the method, the layer of electrothermal layer can be added between the substrate body and the epitaxial layer. In an actual lift off process of the epitaxial layer, only the electrothermal layer is electrically conducted to an external power supply via an electrode, and heating of the electrothermal layer is utilized to heat the epitaxial layer, therefore, a part of the epitaxial layer in contact with the substrate structure can be thermally decomposed and separated from the substrate structure. In addition, the method uses a metal sputtering method to manufacture the electrothermal layer, and has the advantages of high reliability, easy control of a structure and a shape of the electrothermal layer, and the like.

To avoid introduction of impurities, the substrate body can be cleaned, dried, and electrostatically removed in order before metal sputtering.

To better conduct electrical conduction between the electrothermal layer and the external power supply, in some embodiments, before the operation of depositing and growing the epitaxial layer on the electrothermal layer, the method further comprises: forming an electrode on the sidewall of the substrate body by sputtering on the substrate body in the metal sputtering machine using another mask, wherein the electrode is connected to the electrothermal layer. In this way, more reliable electrical conduction between the electrothermal layer and the external power supply can be formed by the electrode.

The forgoing method of depositing and growing the epitaxial layer only needs to use a common method in the art, which is not limited here. In addition, after the epitaxial layer grows, other operations can also refer to common processes in the art.

When the epitaxial layer needs to be separated, the electrode 30 is connected to the external power supply, and the electrothermal layer 20 is heated after the electrical conduction, so that a part of the epitaxial layer in contact with the substrate is thermally decomposed, so as to achieve an objective of separating the epitaxial layer from the substrate structure. In a specific implementation process, if the separation is not complete, the electrothermal layer 20 can be continuously energized until the separation is complete.

It should be understood that the application of the application is not limited to the forgoing examples. For the person skilled in the art, improvements or changes can be made based on the forgoing description, and all these improvements and changes should fall within the protection scope of the appended claims of the application.

What is claimed is:

1. A substrate structure, comprising:
a substrate body; and
an electrothermal layer, arranged on a surface of the substrate body for growing an epitaxial layer.

2. The substrate structure according to claim 1, wherein a structure of the electrothermal layer comprises a hollow grid structure.

3. The substrate structure according to claim 2, wherein the hollow grid structure comprises a plurality of hollow patterns distributed in an array, and the hollow patterns comprise one or more of a square, a rectangle, a circle, a trapezoid, a rhombus, and a parallelogram.

4. The substrate structure according to claim 1, wherein a structure of the electrothermal layer comprises a curved structure.

5. The substrate structure according to claim 4, wherein the curved structure comprises a plurality of curved sections connected in series or in parallel; and the curved section comprises one or more of a S-shaped curved section, a U-shaped curved section, a circular arc-shaped curved section, and a polyline section.

6. The substrate structure according to claim 5, wherein in a case where the curved structure comprises the plurality of U-shaped curved sections connected in series, a distance between two branch lines in each U-shaped curved section is equal.

7. The substrate structure according to claim 1, wherein a material of the electrothermal layer comprises at least one of nickel-chromium alloy, iron-chromium-aluminum alloy, tungsten, tungsten alloy, molybdenum, molybdenum alloy, and carbon fiber.

8. The substrate structure according to claim 1, wherein the substrate body comprises any one of a sapphire substrate, a silicon substrate, a silicon carbide substrate, or a silicon dioxide substrate.

9. The substrate structure according to claim 1, wherein the substrate structure further comprises an electrode, the electrode is connected to the electrothermal layer, and the electrode is configured to electrically conduct the electrothermal layer with an external power supply.

10. The substrate structure according to claim 9, wherein the electrode is arranged on a sidewall of the substrate body and connected to the electrothermal layer.

11. A on-chip structure, comprising:
a substrate; and
an epitaxial layer growing on the substrate;
wherein, the substrate is of a substrate structure which comprises: a substrate body; and an electrothermal layer, arranged on a surface of the substrate body for growing an epitaxial layer.

12. The on-chip structure according to claim 11, wherein the epitaxial layer comprises one or more of a gallium nitride layer, a gallium arsenide layer, an aluminum arsenide layer, and an aluminum nitride layer.

13. A method for manufacturing an on-chip structure, comprising the following operations:
providing a substrate body;
putting the substrate body into a metal sputtering machine;
forming a layer of electrothermal layer on the substrate body by sputtering on the substrate body in the metal sputtering machine using a mask; and
depositing and growing an epitaxial layer on the electrothermal layer.

14. The method for manufacturing the on-chip structure according to claim 13, wherein before the operation of depositing and growing the epitaxial layer on the electrothermal layer, the method further comprises:
forming an electrode on the sidewall of the substrate body by sputtering on the substrate body in the metal sputtering machine using another mask, wherein the electrode is connected to the electrothermal layer.

15. The on-chip structure according to claim 11, wherein the electrothermal layer is located between the substrate body and the epitaxial layer.

16. The on-chip structure according to claim 11, wherein a structure of the electrothermal layer comprises a hollow grid structure.

17. The on-chip structure according to claim 16, wherein the hollow grid structure comprises a plurality of hollow patterns distributed in an array, and the hollow patterns comprise one or more of a square, a rectangle, a circle, a trapezoid, a rhombus, and a parallelogram.

18. The method for manufacturing the on-chip structure according to claim 13, wherein before the operation of forming a layer of electrothermal layer on the substrate body by sputtering on the substrate body in the metal sputtering machine using a mask, the method further comprises:
cleaning, drying and destaticizing the substrate body in turn.

19. The method for manufacturing the on-chip structure according to claim 13, wherein a structure of the electrothermal layer comprises a hollow grid structure.

20. The method for manufacturing the on-chip structure according to claim 19, wherein the hollow grid structure comprises a plurality of hollow patterns distributed in an array, and the hollow patterns comprise one or more of a square, a rectangle, a circle, a trapezoid, a rhombus, and a parallelogram.
